(19) United States
(12) Patent Application Publication
(10) Pub. No.: US 2018/0342892 A1
(43) Pub. Date: Nov. 29, 2018

(54) PHOTOVOLTAIC ENERGY STORAGE DEVICE, CABINET AND PHOTOVOLTAIC ENERGY STORAGE SYSTEM

(71) Applicant: SUNGROW POWER SUPPLY CO., LTD., Hefei (CN)

(72) Inventors: Chenghua ZHOU, Hefei (CN); Guohong LI, Hefei (CN); Sigen ZHENG, Hefei (CN)

(21) Appl. No.: 15/650,040

(22) Filed: Jul. 14, 2017

(30) Foreign Application Priority Data
May 27, 2017 (CN) 201720614786.5

(51) Int. Cl. H02J 7/35; G21H 1/12; H02J 7/00; H01M 10/44; H01L 31/053; H02S 40/38

(52) U.S. Cl. CPC H02J 7/35; G21H 1/12; H02S 40/38; H01M 10/441; H01L 31/053; H02J 7/0013

(57) ABSTRACT

A photovoltaic energy storage device includes a battery module group, a battery switching device, an EMS controller, a direct current circuit breaker, an inverter and an alternating current circuit breaker. The battery module group, the battery switching device and the EMS controller are integrated in a first insulation compartment of the photovoltaic energy storage device; and the direct current circuit breaker, the inverter and the alternating current circuit breaker are integrated in a second insulation compartment of the photovoltaic energy storage device. A thermal-protective coating is arranged between the first insulation compartment and the second insulation compartment. Therefore, the integration of the photovoltaic energy storage device is divided into two parts, i.e., an integration at a battery side and an integration at an inverter side, and the thermal-protective coating is arranged, to prevent heat convection and heat exchange between the battery side and the inverter side.

### CROSS-REFERENCE TO RELATED APPLICATIONS

The present invention claims priority under 35 U.S.C. § 119 to Chinese Patent Application No. 201720614786.5 filed in China on May 27, 2017, the entire content of which is incorporated herein by reference.

### FIELD

The present application relates to the technical field of photovoltaic power generation, and in particular to a photovoltaic energy storage device, a cabinet and a photovoltaic energy storage system.

### BACKGROUND

With the continuous development of society, energy is continuously decreased, and a photovoltaic power generation system is developed rapidly. Inventors of the present application found that, an energy storage battery has a high degree of integration in a conventional domestic photovoltaic power generation system; however, the manner of connection among the energy storage battery, an energy storage inverter, an energy management system (abbreviated as EMS) control system, a direct current to direct current (abbreviated as DC-DC) convertor, an alternating current power distribution device, a direct current power distribution device and the like is complicated. Generally, in installation and maintenance, multiple integrated cabinets need to be installed on site, and a higher using requirement is imposed on a user, for example, the user needs to operate and control multiple devices at the same time.

Therefore, it becomes a big technical problem to be solved urgently that how to provide a photovoltaic energy storage system which can realize a high degree of integration and is convenient to maintain.

### SUMMARY

In view of this, a photovoltaic energy storage system is provided according to the present application, which has a high degree of integration, has a simple connection manner and is easy to maintain.

A photovoltaic energy storage device is provided according to the present application, which includes a battery module group, a battery switching device, an energy management system controller, a direct current circuit breaker, an inverter and an alternating current circuit breaker;

wherein, the battery module group, the battery switching device and the energy management system controller are integrated in a first insulation compartment of the photovoltaic energy storage device, and the direct current circuit breaker, the inverter and the alternating current circuit breaker are integrated in a second insulation compartment of the photovoltaic energy storage device; and

a thermal-protective coating is arranged between the first insulation compartment and the second insulation compartment.

Optionally, the battery module group includes multiple battery modules battery modules being arranged in an array configuration;

a first column of battery module group includes M battery modules having the same sizes, and the battery switching device is arranged at a preset position of the first column of the battery module group; and

a second column of battery module group includes N battery modules having the same sizes, and each of M and N is a positive integer greater than or equal to one, and M is smaller than or equal to N.

Optionally, the first column of battery module group includes eight battery modules having the same sizes, and the battery switching device has the same size as the battery module and is arranged above the first column of battery module group;

and/or,

the second column of battery module group includes nine battery modules having the same sizes.

Optionally, the energy management system controller is arranged at a preset position above the battery module group, and is electrically connected to the battery switching device and the inverter.

Optionally, the direct current circuit breaker, the inverter and the alternating current circuit breaker are arranged successively in the second insulation compartment from top to bottom.

Optionally, the thermal-protective coating includes a metal plate insulation baffle and/or a heat-insulation cotton material.

A cabinet includes a cabinet body and a door assembly;

the cabinet body has a first insulation compartment and a second insulation compartment; and

the door assembly includes a first cabinet door and a second cabinet door which are detachably connected to the first insulation compartment, and a third cabinet door which is detachably connected to the second insulation compartment.

Optionally, a first ventilation opening is arranged above the cabinet body and a second ventilation opening is arranged at a preset position of the door assembly.

Optionally, the cabinet body is a cabinet formed by bending cold-rolled plates.

A photovoltaic energy storage system includes any one of the cabinets described above and any one of the photovoltaic energy storage devices described above.

It can be known from the above technical solutions that, a photovoltaic energy storage device is provided according to the present application, which includes a battery module group, a battery switching device, an EMS controller, a direct current circuit breaker, an inverter and an alternating current circuit breaker. The battery module group, the battery switching device and the EMS controller are integrated in a first insulation compartment of the photovoltaic energy storage device; and the direct current circuit breaker, the inverter and the alternating current circuit breaker are integrated in a second insulation compartment of the photovoltaic energy storage device. A thermal-protective coating is arranged between the first insulation compartment and the second insulation compartment. Therefore, in this technical solution, the integration of the photovoltaic energy storage device is divided into two parts, i.e., an integration at a battery side and an integration at an inverter side, and the thermal-protective coating is arranged, to prevent heat convection and heat exchange between the battery side and the inverter side, thereby making the photovoltaic energy storage device have a high degree of integration, easy to install, and convenient to be operated by a user.

### BRIEF DESCRIPTION OF THE DRAWINGS

In order to more clearly illustrate embodiments of the present application or the technical solutions of the conventional technology, drawings referred to describe the embodiments or the conventional technology will be briefly described hereinafter. Apparently, the drawings in the following description are only some embodiments of the present application, and for those skilled in the art, other drawings may be obtained based on the drawings provided without any creative efforts.

FIG. 1 is a schematic view showing the structure of a photovoltaic energy storage device according to an embodiment of the present application;

FIG. 2 is a schematic view showing the structure of another photovoltaic energy storage device according to an embodiment of the present application;

FIG. 3 is a schematic view showing the structure of a cabinet according to an embodiment of the present application;

FIG. 4 is a schematic side view showing the structure of a photovoltaic energy storage device according to an embodiment of the present application; and

FIG. 5 is a schematic view showing the structure of a photovoltaic energy storage system according to an embodiment of the present application.

### DETAILED DESCRIPTION OF THE EMBODIMENTS

The technical solutions in the embodiments of the present application will be described clearly and completely hereinafter in conjunction with the drawings in the embodiments of the present application. Apparently, the described embodiments are only a part of the embodiments of the present application, rather than all embodiments. Based on the embodiments in the present application, all of other embodiments, made by the person skilled in the art without any creative efforts, fall into the scope of protection of the present application.

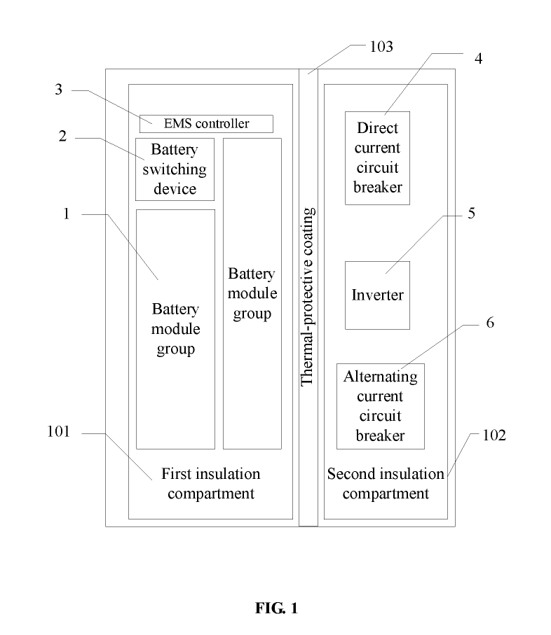

Reference is made to FIG. 1, which is a photovoltaic energy storage device according to an embodiment of the present application. The photovoltaic energy storage device includes a battery module group 1, a battery switching device 2, an Energy Management System (abbreviated as EMS) controller 3, a direct current circuit breaker 4, an inverter 5 and an alternating current circuit breaker 6.

The battery module group 1, the battery switching device 2 and the EMS controller 3 are integrated in a first insulation compartment 101 of the photovoltaic energy storage device; the direct current circuit breaker 4, the inverter 5 and the alternating current circuit breaker 6 are integrated in a second insulation compartment 102 of the photovoltaic energy storage device. A thermal-protective coating 103 is arranged between the first insulation compartment 101 and the second insulation compartment 102.

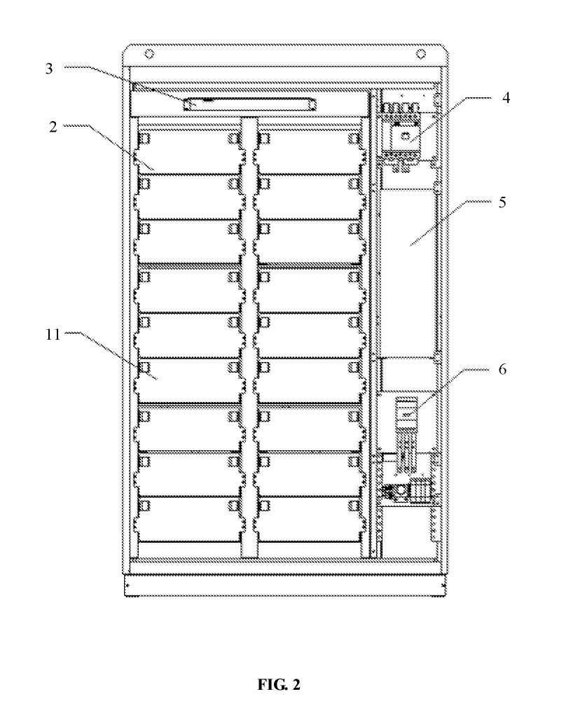

The thermal-protective coating may be made of a metal plate insulation baffle and/or a heat-insulation cotton material. As shown in FIG. 2, the battery module group includes multiple battery modules 11 being arranged in an array configuration.

A first column of battery module group includes M battery modules having the same sizes, and the battery switching device is arranged at a preset position of the first column of the battery module group.

A second column of battery module group includes N battery modules having the same sizes. Each of M and N is a positive integer greater than or equal to one, and M is smaller than or equal to N.

It is preferable that, in this embodiment, the first column of battery module group includes eight battery modules 11 having the same sizes, the second column of battery module group includes nine battery modules 11 having the same sizes, and the battery switching device 2 is configured to have the same size as the battery module 11 and is arranged above the first column of battery module group. In this embodiment, the battery module 11 may employ a 22-cell ternary lithium battery, with a capacity of 7.61 kwh and a size of 370×580×160. The overall dimension of the energy storage device having two columns of nine battery modules in this embodiment is 1200×2034×800 (w×h×d), thus compared to other batteries, the overall frame occupies a small space, and the design in a width direction and a height direction of the energy storage device are fully designed according to possible widths and heights of an interior door. Thus, the ergonomic design is good, it is convenient to install and maintain, and a single battery has a higher capacity, thereby improving an integrated capacity of the whole photovoltaic energy storage device.

Besides, the battery switching device 2 may be installed above the battery module 11, and may also be installed under the battery module 11. In order to facilitate the operation of a user, in this embodiment, the battery switching device 2 is installed above the battery module 11.

Based on the foregoing embodiments, the EMS controller 3 is arranged at a preset place above the battery module group 1, and is electrically connected to the battery switching device and the inverter. The EMS controller 3 is mainly configured to control the battery switching device 2 (for example, a battery switch gear) and the inverter 5 and to communicate with an external device.

As shown in FIG. 2, the direct current circuit breaker 4, the inverter 5 and the alternating current circuit breaker 6 are successively arranged in the second insulation compartment from top to bottom. The direct current circuit breaker 4 is configured to be connected and disconnected from the battery switching device 2, the inverter 5 is configured to convert a direct current to an alternating current, and finally the alternating current circuit breaker 6 is configured to be connected and disconnected from a mains supply or a micro-grid.

In conclusion, the direct current circuit breaker 4, the inverter 5 and the alternating current circuit breaker 6 are integrated in one insulation compartment, thereby improving the integration level of the whole photovoltaic energy storage device.

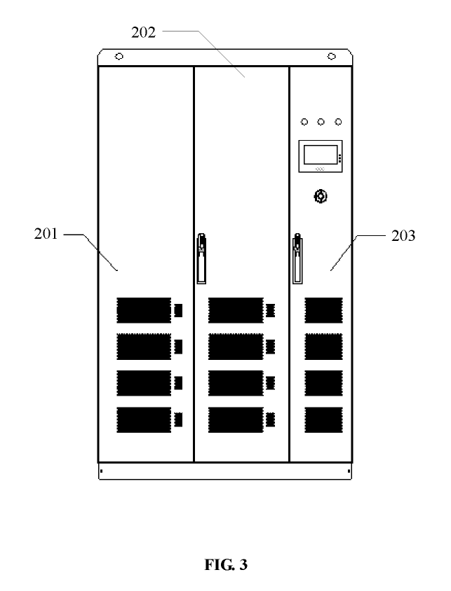

Based on the above embodiments, as shown in FIG. 3, a cabinet is further provided according to this embodiment. The cabinet includes a cabinet body and a door assembly. The cabinet body has a first insulation compartment and a second insulation compartment. The door assembly includes a first cabinet door 201 and a second cabinet door 202 which are detachably connected to the first insulation compartment, and a third cabinet door 203 which is detachably connected to the second insulation compartment.

The cabinet door and the respective insulation compartment may be movably connected, that is, for the front door of the cabinet, a battery-side door plate and an inverter-side door plate are separately designed, which is different from the normal design which has only a single door. By providing separate door plates, it is convenient to maintain the part which has a problem. A height of an individual cabinet may be adjusted according to the battery capacity, thereby facilitating indoor transportation.

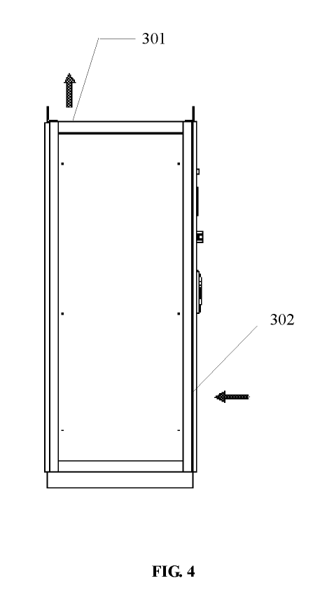

Besides, as shown in FIG. 4, in this embodiment, a first ventilation opening 301 is arranged above the cabinet body, and a second ventilation opening 302 is arranged at a preset position of the door assembly. Thermal dissipation of the cabinet is also separately designed for the left compartment and the right compartment (that is the first insulation compartment and the second insulation compartment).

Thermal dissipation of the battery side is realized by introducing air from the front door and discharging air from the roof to exchange heat with indoor air. Since the operation of a battery module has a high demand for an environmental temperature, an air conditioner may be installed indoors or a room with a low environment temperature may be selected to guarantee the operational stability of the batteries.

Similarly, thermal dissipation of the inverter side is consistent with thermal dissipation of the battery side, which is realized by introducing air from the front door and discharging air from the roof to exchange heat with indoor air. An air inlet of the inverter may be spaced from the ground by a distance of 500 mm, thereby greatly decreasing the wind resistance in the air introducing process.

In other words, in the overall thermal dissipation design, the characteristic that the indoor temperature is not very high is utilized at the battery side, and the design of installing an air conditioner in the energy storage cabinet is cancelled, thereby saving the design cost and the subsequent use and maintenance costs. In a specific design, an installation position of an energy storage product and the selection of an indoor air conditioner may be determined according to the capacity of the battery.

Besides, in this embodiment, the cabinet body is preferably made of bending cold-rolled plates. That is, the overall design of the cabinet employs bending cold-rolled plates and integral welding. The usage of bending parts reduces the design cost and the processing cost, and the integral welding ensures the load bearing strength of the whole cabinet. The door of the cabinet may also employ the installation method of a standard bending cabinet, which may also lower the design cost.

Based on the foregoing embodiments, a photovoltaic energy storage system is further provided according to this embodiment. The photovoltaic energy storage system includes any one of the cabinets described above and any one of the photovoltaic energy storage devices described above.

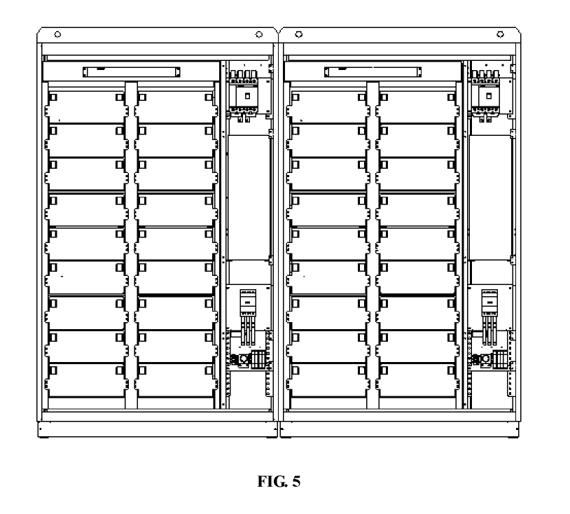

Furthermore, as shown in FIG. 5, according to a practical design requirement, the capacity of the photovoltaic energy storage system is capable to be expanded greatly, for example, by connecting multiple photovoltaic energy storage devices in parallel, thereby meeting the battery charging demand of an electric car for the gradually maturing market of the new energy automobiles.

It can be known from the above technical solutions that, a photovoltaic energy storage device is provided according to the present application, which includes a battery module group, a battery switching device, an EMS controller, a direct current circuit breaker, an inverter and an alternating current circuit breaker. The battery module group, the battery switching device and the EMS controller are integrated in a first insulation compartment of the photovoltaic energy storage device; and the direct current circuit breaker, the inverter and the alternating current circuit breaker are integrated in a second insulation compartment of the photovoltaic energy storage device. A thermal-protective coating is arranged between the first insulation compartment and the second insulation compartment. Therefore, in this technical solution, the integration of the photovoltaic energy storage device is divided into two parts, i.e., an integration at a battery side and an integration at an inverter side, and the thermal-protective coating is arranged, to prevent heat convection and heat exchange between the battery side and the inverter side, thereby making the photovoltaic energy storage device have a high degree of integration, easy to install, and convenient to be operated by a user.

The above embodiments in the specification are described in a progressive manner. Each of the embodiments is mainly focused on describing its differences from other embodiments, and references may be made among these embodiments with respect to the same or similar portions among these embodiments.

Based on the above description of the disclosed embodiments, the person skilled in the art is capable of carrying out or using the present application. It is obvious for the person skilled in the art to make many modifications to these embodiments. The general principle defined herein may be applied to other embodiments without departing from the spirit or scope of the present application. Therefore, the present application is not limited to the embodiments illustrated herein, but should be defined by the broadest scope consistent with the principle and novel features disclosed herein.

What is claimed is:

1. A photovoltaic energy storage device, comprising a battery module group, a battery switching device, an energy management system controller, a direct current circuit breaker, an inverter and an alternating current circuit breaker;
wherein, the battery module group, the battery switching device and the energy management system controller are integrated in a first insulation compartment of the photovoltaic energy storage device, and the direct current circuit breaker, the inverter and the alternating current circuit breaker are integrated in a second insulation compartment of the photovoltaic energy storage device; and
a thermal-protective coating is arranged between the first insulation compartment and the second insulation compartment.

2. The photovoltaic energy storage device according to claim 1, wherein the battery module group comprises a plurality of battery modules being arranged in an array configuration;
a first column of battery module group comprises M battery modules having the same sizes, and the battery switching device is arranged at a preset position of the first column of the battery module group; and
a second column of battery module group comprises N battery modules having the same sizes, and each of M and N is a positive integer greater than or equal to one, and M is smaller than or equal to N.

3. The photovoltaic energy storage device according to claim 2, wherein the first column of battery module group comprises eight battery modules having the same sizes, and the battery switching device has the same size as the battery module and is arranged above the first column of battery module group;
and/or,
the second column of battery module group comprises nine battery modules having the same sizes.

4. The photovoltaic energy storage device according to claim 2, wherein the energy management system controller is arranged at a preset position above the battery module group, and is electrically connected to the battery switching device and the inverter.

5. The photovoltaic energy storage device according to claim 2, wherein the direct current circuit breaker, the inverter and the alternating current circuit breaker are arranged successively in the second insulation compartment from top to bottom.

6. The photovoltaic energy storage device according to claim 1, wherein the thermal-protective coating comprises a metal plate insulation baffle and/or a heat-insulation cotton material.

7. A cabinet, comprising a cabinet body and a door assembly;
the cabinet body having a first insulation compartment and a second insulation compartment; and
the door assembly comprising a first cabinet door and a second cabinet door which are detachably connected to the first insulation compartment, and a third cabinet door which is detachably connected to the second insulation compartment.

8. The cabinet according to claim 7, wherein a first ventilation opening is arranged above the cabinet body and a second ventilation opening is arranged at a preset position of the door assembly.

9. The cabinet according to claim 7, wherein the cabinet body is a cabinet formed by bending cold-rolled plates.

10. A photovoltaic energy storage system, comprising a cabinet and a photovoltaic energy storage device, wherein
the cabinet comprises a cabinet body and a door assembly;
the cabinet body has a first insulation compartment and a second insulation compartment; and
the door assembly comprises a first cabinet door and a second cabinet door which are detachably connected to the first insulation compartment, and a third cabinet door which is detachably connected to the second insulation compartment; and
wherein, the photovoltaic energy storage device comprises a battery module group, a battery switching device, an energy management system controller, a direct current circuit breaker, an inverter and an alternating current circuit breaker;
wherein, the battery module group, the battery switching device and the energy management system controller are integrated in the first insulation compartment, and the direct current circuit breaker, the inverter and the alternating current circuit breaker are integrated in the second insulation compartment; and
a thermal-protective coating is arranged between the first insulation compartment and the second insulation compartment.

11. The photovoltaic energy storage system according to claim 10, wherein the battery module group comprises a plurality of battery modules being arranged in an array configuration;
a first column of battery module group comprises M battery modules having the same sizes, and the battery switching device is arranged at a preset position of the first column of the battery module group; and
a second column of battery module group comprises N battery modules having the same sizes, and each of M and N is a positive integer greater than or equal to one, and M is smaller than or equal to N.

12. The photovoltaic energy storage system according to claim 11, wherein the first column of battery module group comprises eight battery modules having the same sizes, and the battery switching device has the same size as the battery module and is arranged above the first column of battery module group;
and/or,
the second column of battery module group comprises nine battery modules having the same sizes.

13. The photovoltaic energy storage system according to claim 11, wherein the energy management system controller is arranged at a preset position above the battery module group, and is electrically connected to the battery switching device and the inverter.

14. The photovoltaic energy storage system according to claim 11, wherein the direct current circuit breaker, the inverter and the alternating current circuit breaker are arranged successively in the second insulation compartment from top to bottom.

15. The photovoltaic energy storage system according to claim 10, wherein the thermal-protective coating comprises a metal plate insulation baffle and/or a heat-insulation cotton material.

16. The photovoltaic energy storage system according to claim 10, wherein a first ventilation opening is arranged above the cabinet body and a second ventilation opening is arranged at a preset position of the door assembly.

17. The photovoltaic energy storage system according to claim 10, wherein the cabinet body is a cabinet formed by bending cold-rolled plates.
